(19) United States
(12) Patent Application Publication
(10) Pub. No.: US 2026/0206129 A1
(43) Pub. Date: Jul. 16, 2026

(54) ELECTRONIC DEVICE CAPABLE OF OPERATING WITH BATTERY INSTALLED

(71) Applicant: WISTRON NEWEB CORPORATION, HSINCHU (TW)

(72) Inventor: WEN-TSAN CHUNG, HSINCHU (TW)

(21) Appl. No.: 19/173,880

(22) Filed: Apr. 9, 2025

(30) Foreign Application Priority Data
Jan. 15, 2025 (TW) 114101567

(51) Int. Cl. H05K 1/02; H01Q 1/22

(52) U.S. Cl. CPC H05K 1/0243; H01Q 1/22; H05K 2201/1003; H05K 2201/10037; H05K 2201/10098

(57) ABSTRACT

An electronic device is capable of operating with a battery installed, and the electronic device includes a substrate, an antenna, a system ground portion, a battery ground portion, and an inductor element. The antenna is disposed on the substrate, the system ground portion is disposed on the substrate, and the battery ground portion is configured to be connected to a negative terminal of the battery. The battery ground portion and the system ground portion are separate from each other, and the inductor element is connected between the battery ground portion and the system ground portion.

### CROSS-REFERENCE TO RELATED PATENT APPLICATION

This application claims the benefit of priority to Taiwan Patent Application No. 114101567, filed on January 15, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

An electronic device, particularly an electronic device capable of operating with a battery installed.

### BACKGROUND OF THE DISCLOSURE

FIGS. 1A-1C show an example of a conventional electronic device 100. The electronic device 100 includes a substrate 102, and the substrate 102 has a first surface (as shown in FIG. 1A) and a second surface (as shown in FIG. 1B). The first surface is mainly provided for allowing an antenna 104 and other components such as a processor, switches, etc. (not shown in the drawings) to be disposed thereon, while the second surface is mainly provided for allowing a positive contact 110 and a negative contact 112 to be disposed thereon for a battery. The positive contact 110 and the negative contact 112 are respectively used to contact a positive terminal and a negative terminal of a battery 114, allowing the battery 114 to be installed onto the electronic device 100 (as shown in FIG. 1C) for operation. In actual situations, if the battery manufacturer marks the positive and negative terminals, a "+" mark can be seen on the battery shell at the positive terminal of the battery 114, and a "-" mark can be seen on the battery shell at the negative terminal of the battery 114. The electronic device 100 can feed signals to the antenna 104 through a feed portion 101. The electronic device 100 has a system ground portion 115, which can be viewed as being distributed on the first and second surfaces of the substrate 102 for simplicity, and the system ground portion 115 is connected to the negative contact 112. If the substrate 102 is a multilayer board, the system ground portion 115 can also be located in an intermediate layer between the first and second surfaces. Different layers of the system ground portion 115 can be connected through vias for conduction. Depending on the design of the antenna 104, the antenna 104 may also include an antenna ground portion (not shown in FIGS. 1A-1C) connected to the system ground portion 115. In some configurations, one end of the feed portion 101 feeding signals to the antenna 104 may be grounded together with the system ground portion 115. In this example, the battery 114 is a lithium battery, but can also be other types of batteries. The electronic device 100 can be applied in scenarios such as door and window sensors; for example, the electronic device 100 can be equipped with a reed switch (not shown in the drawings) to work with a separate magnet structure (not shown in the drawings) to detect the opened or closed state of doors, windows, or other similar structures. For instance, the electronic device 100 can be installed on the body of a door or window, while the corresponding magnet structure can be installed on the frame of the door or window. When the door or window is opened or closed, the electronic device 100 can determine the state of the door or window based on whether the electronic device 100 is close to or far away from the magnet structure, and accordingly send a signal through the antenna 104 to the user's mobile phone, computer, or other devices, informing the user whether the door or window at home is open. The electronic device 100 may also be applied in other scenarios.

However, the conventional electronic device 100 still has room for improvement in terms of signal quality of the antenna 104. For example, in applications of door and window sensors, it has been found that the existing electronic device 100 has poor signal quality, making it difficult for the hub or mobile phone used with the electronic device 100 to properly receive signals from the electronic device 100, or causing the reception distance to be too short.

Analysis reveals that the above problems may arise from the following reasons. Firstly, the substrate 102 usually has an antenna clearance region 106 defined around the area where the antenna 104 is located, and the placement of components that would interfere with the antenna 104 in the antenna clearance region 106 is avoided as much as possible. However, current markets tend toward designing lightweight and multifunctional products, so the electronic device 100 may need to have many components placed in a limited space, leading to some components overlapping with the antenna clearance region 106. For example, as shown in FIG. 1C, when the battery 114 is installed in the electronic device 100, the body of the battery 114 partially overlaps with the antenna clearance region 106, thereby affecting the signal quality of the antenna 104. Secondly, door and window sensor products usually operate at frequencies below 1 GHz (e.g., Z-Wave band), requiring the antenna 104 to be designed with a corresponding length for the operating frequency; however, the development process is limited by product size, resulting in an insufficient electrical length of the antenna 104 and thereby weakening the characteristics of the antenna 104. Thirdly, the negative terminal of the battery 114 used in the product is connected to the system ground portion 115 of the electronic device 100, causing the battery 114 and the antenna 104 to share the system ground portion 115, which also weakens the characteristics of the antenna 104. Under the influence of the above factors, the characteristics of the antenna 104 are severely affected.

Therefore, a solution is needed to overcome the aforementioned problems and improve the signal quality of the antenna.

### SUMMARY OF THE DISCLOSURE

The present disclosure provides an electronic device capable of operating with a battery installed, which can overcome the problems of the conventional techniques described above.

In some embodiments, an electronic device capable of operating with a battery installed is provided. The electronic device includes: a substrate; an antenna disposed on the substrate; a system ground portion disposed on the substrate; a battery ground portion configured to be connected to a negative terminal of the battery; and an inductor element. The battery ground portion and the system ground portion are separate from each other, and the inductor element is connected between the battery ground portion and the system ground portion.

In other embodiments, an electronic device capable of operating with a battery installed is provided. The electronic device includes: a substrate including an antenna clearance region; an antenna disposed in the antenna clearance region; a system ground portion disposed on the substrate; and a battery ground portion configured to be connected to a negative terminal of the battery. A projected area of the battery ground portion and a projected area of the antenna clearance region projected on the substrate do not overlap.

These and other aspects of the present disclosure will become apparent from the following description of the embodiment taken in conjunction with the attached drawings and their captions, although variations and modifications therein may be affected without departing from the spirit and scope of the present disclosure.

### BRIEF DESCRIPTION OF THE DRAWINGS

The described embodiments may be better understood by reference to the following description and the accompanying drawings.

FIGS. 1A-1C show schematic views of a conventional electronic device.

FIGS. 2A-2B show schematic views of an electronic device according to a first embodiment of the present disclosure.

FIGS. 3A-3D show schematic views of an electronic device according to a second embodiment of the present disclosure.

FIGS. 4A-4C show schematic views of an electronic device according to a third embodiment of the present disclosure.

FIGS. 5A-5C show various extension configurations of an extended ground portion according to some embodiments of the present disclosure.

FIG. 6 shows an antenna efficiency graph under different configurations of the electronic device.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like. The term “connect” as used herein should be interpreted as having direct or indirect physical connections between components. The term “couple” as used herein should be interpreted as having energy coupling between components that are separated without physical contact.

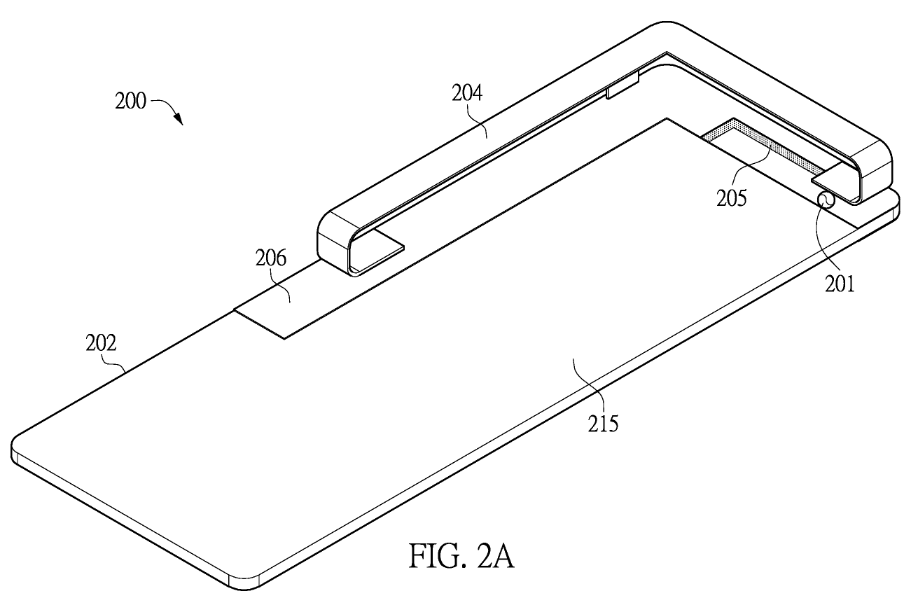

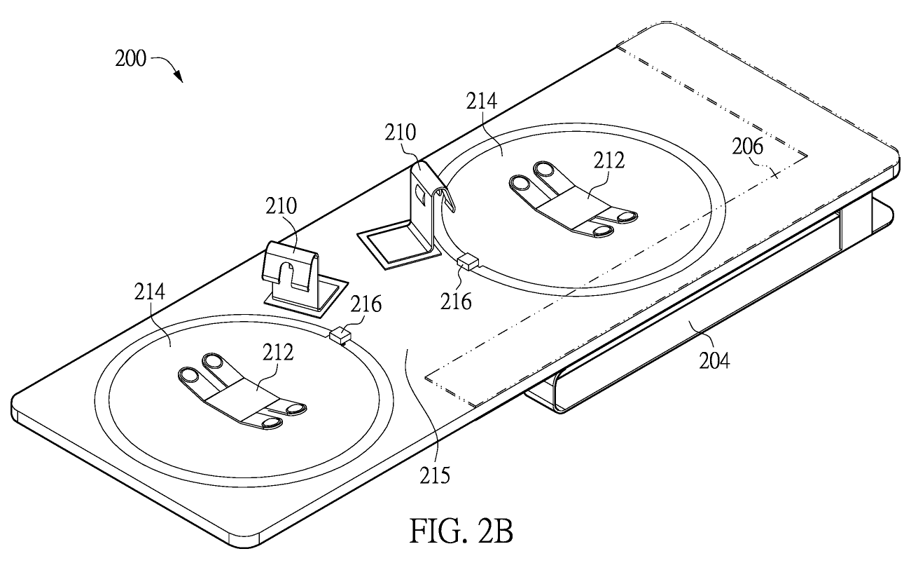

FIGS. 2A-2B show a schematic view of an electronic device 200 capable of operating with a battery installed according to a first embodiment of the present disclosure. The electronic device 200 includes a substrate 202 which has a first surface (as shown in FIG. 2A) and a second surface (as shown in FIG. 2B). The first surface can allow an antenna 204 and other components such as processors and switches (not shown) to be disposed thereon, and the second surface can allow a positive contact 210 and a negative contact 212 to be disposed thereon. When the battery is installed in the electronic device 200, the positive contact 210 and the negative contact 212 are configured to respectively contact the positive and negative terminals of the battery, allowing the electronic device 200 to operate. In actual situations, if the battery manufacturer marks the positive and negative terminals, a "+" mark can be seen on the battery shell at the positive terminal of the battery, and a "-" mark can be seen on the battery shell at the negative terminal. The electronic device 200 can feed signals to the antenna 204 through a feed portion 201, wherein the position of the feed portion 201 can vary and is not limited to those shown in the drawings (e.g., FIG. 2A).

The electronic device 200 includes a system ground portion 215 disposed on the substrate 202. In actual applications, the circuit system of the electronic device 200 can include components such as a processor, reed switch, or other electronic components (not shown in the drawings), and the system ground portion 215 can serve as the ground portion of the circuit system of the electronic device 200. The system ground portion 215 is distributed on the first and/or second surfaces of the substrate 202. If the substrate 202 is a multilayer board, the system ground portion 215 can also be located in an intermediate layer between the first and second surfaces. The layout pattern of the system ground portion 215 can vary and may need to be modified due to the placement of other components (not shown in the drawings), so the layout pattern of the system ground portion 215 shown in the drawings is for reference only, and the present disclosure is not limited thereto. In some embodiments, depending on the design of the antenna 204, the antenna 204 may include an antenna ground portion 205 connected to the system ground portion 215, and the shape of the antenna ground portion 205 can vary and is not limited to those shown in the drawings (e.g., FIG. 2A). Additionally, in some variant embodiments, one end of the feed portion 201 feeding signals to the antenna 204 may be grounded together with the system ground portion 215. The substrate 202 includes an antenna clearance region 206. Placement of components in the antenna clearance region 206 should be avoided as much as possible to prevent affecting the signal quality of the antenna 204; therefore, in this embodiment, the system ground portion 215 is placed outside the antenna clearance region 206. In practice, the feed portion 201 and/or the antenna ground portion 205 may still occupy a small part of the antenna clearance region 206.

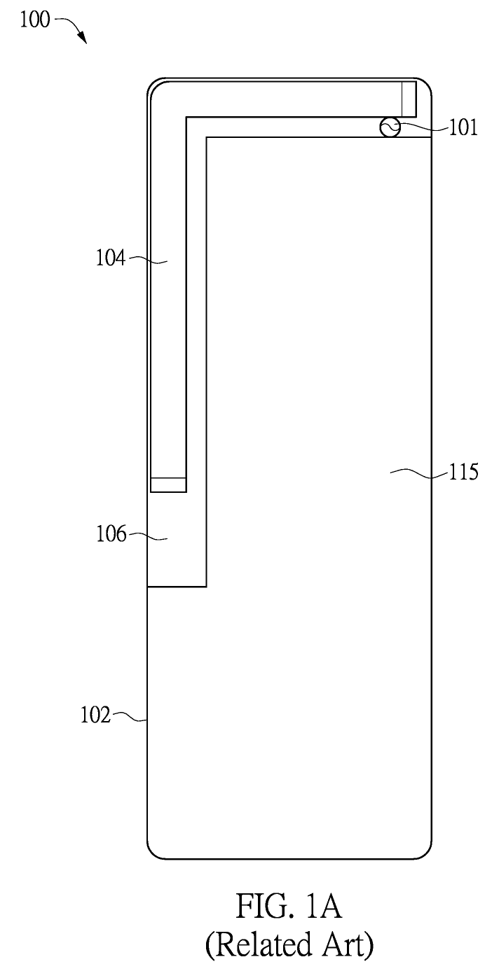

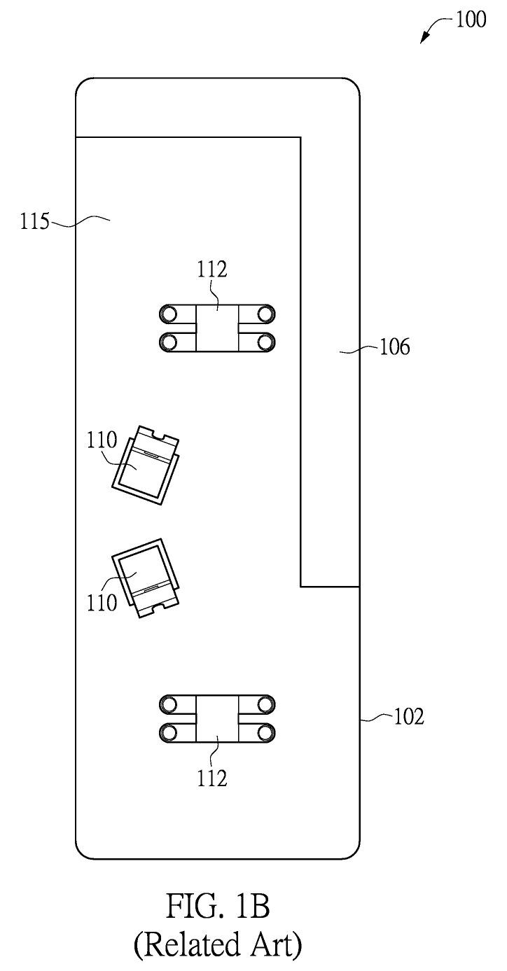

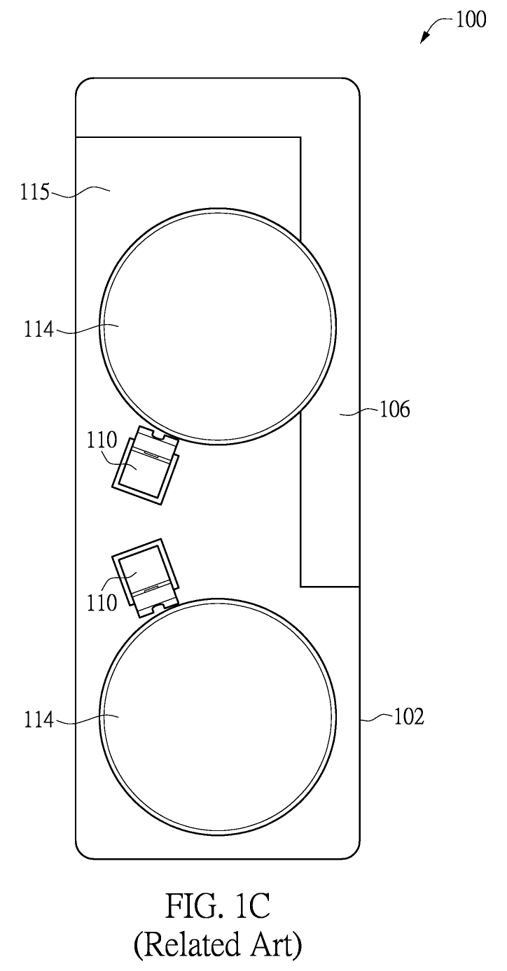

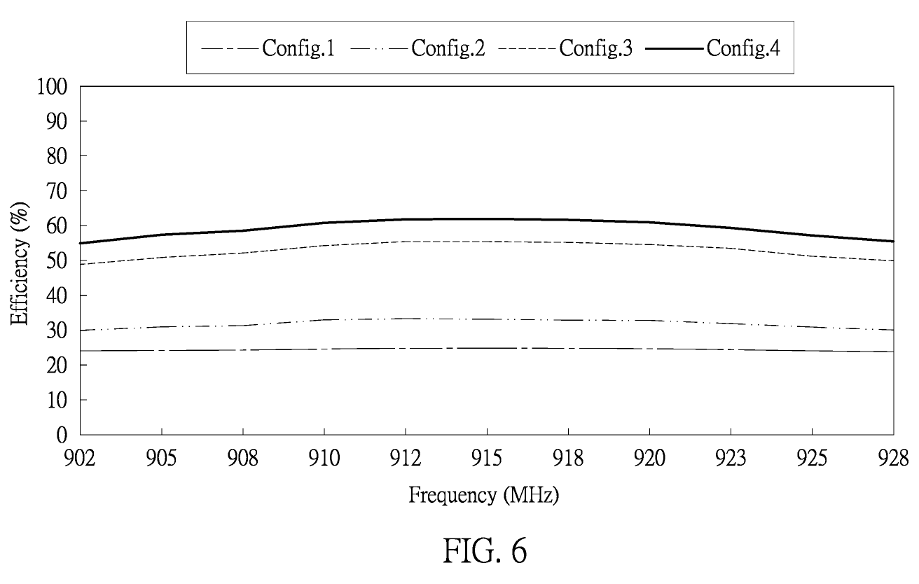

Compared to the conventional techniques shown in FIGS. 1A-1C, the present disclosure provides a separate ground area for the battery in the embodiment shown in FIGS. 2A-2B; that is, the system ground portion 215 is separate from the battery ground portion 214. As shown in FIG. 2B, the electronic device 200 can have two batteries installed, wherein the positive contact 210 and the negative contact 212 can respectively contact the positive and negative terminals of one of the batteries, and the negative contact 212 is connected to the battery ground portion 214. In this embodiment, the system ground portion 215 surrounds the battery ground portion 214, but the battery ground portion 214 does not directly contact the system ground portion 215; instead, the battery ground portion 214 and the system ground portion 215 are connected through an inductor element 216. In other words, the inductor element 216 is connected between the system ground portion 215 and the battery ground portion 214. The term "inductor element" in the present disclosure can refer to any component capable of generating impedance to high-frequency signals, such as inductors, RF (Radio Frequency) chokes, ferrite beads, printed circuit equivalents, or equivalent circuits assembled from any electronic components. Although the battery ground portion 214 and the antenna clearance region 206 in this embodiment have partially overlapping projected areas on the substrate 202 (refer to FIG. 2B), separating the system ground portion 215 and the battery ground portion 214 with the inductor element 216 can reduce interference from the battery to the antenna 204, and the efficiency of the antenna 204 has been improved. The data on antenna efficiency will be further described later with reference to FIG. 6.

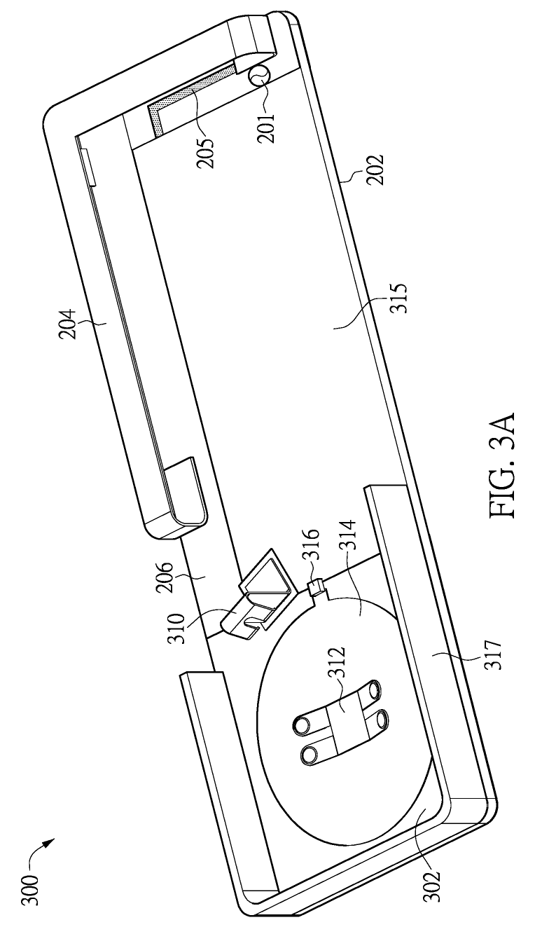

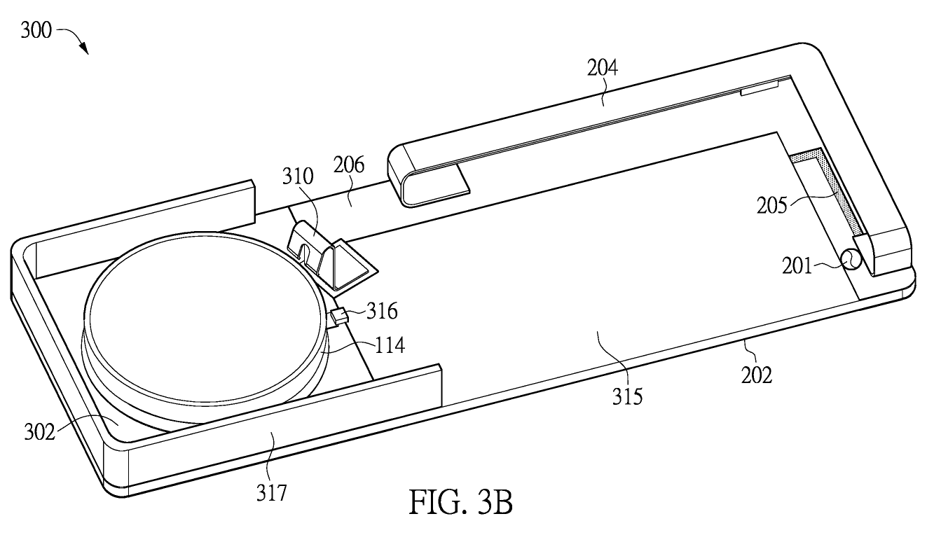

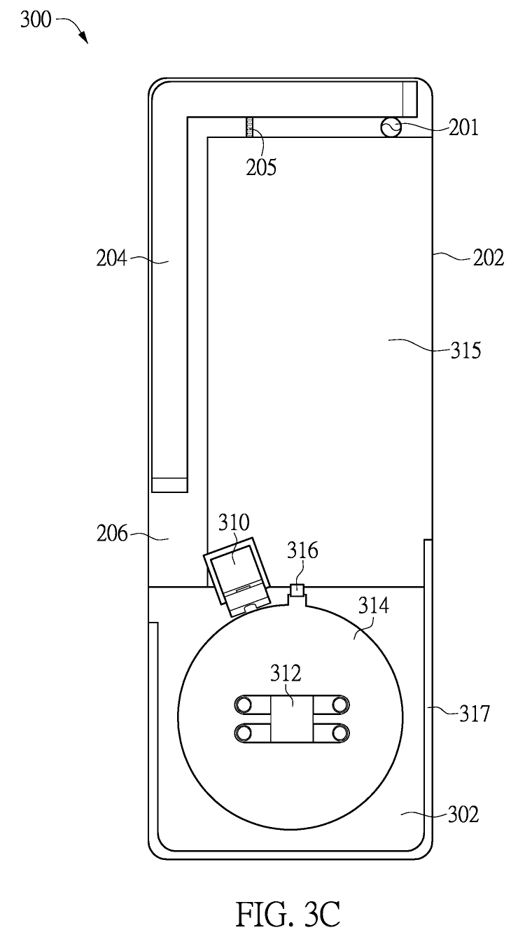

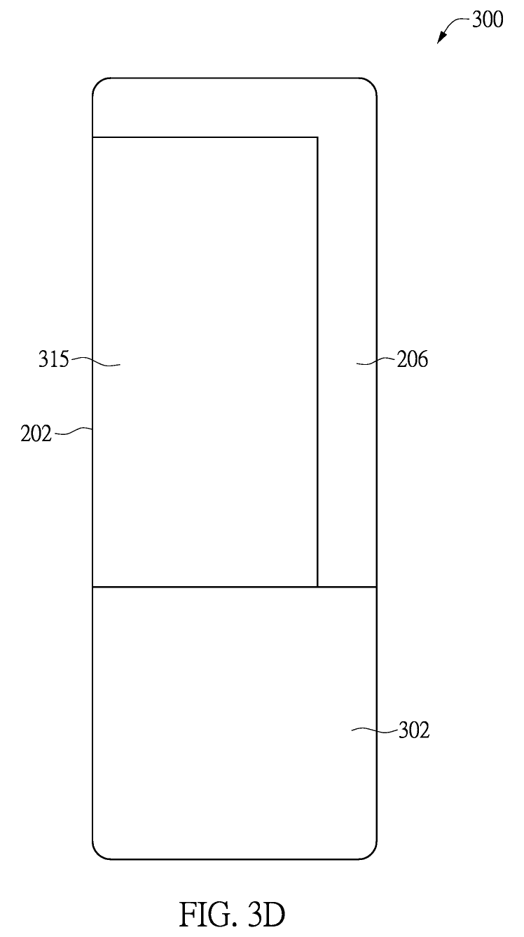

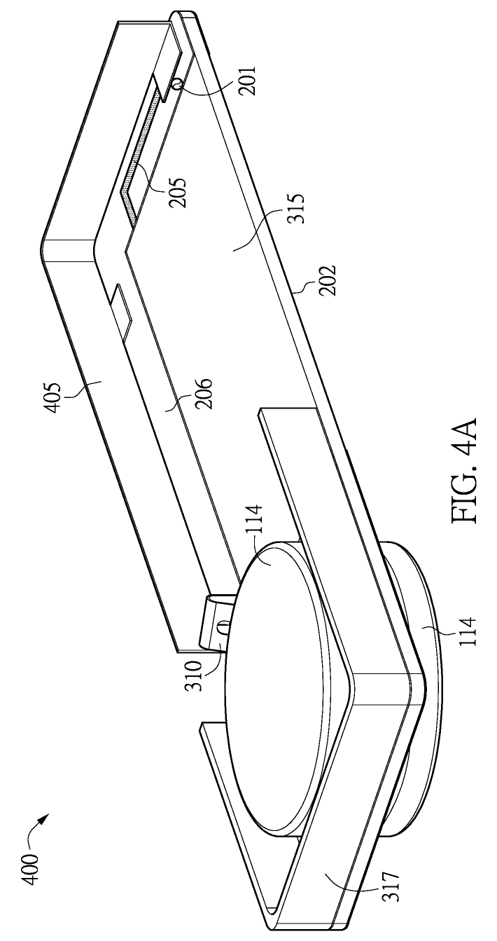

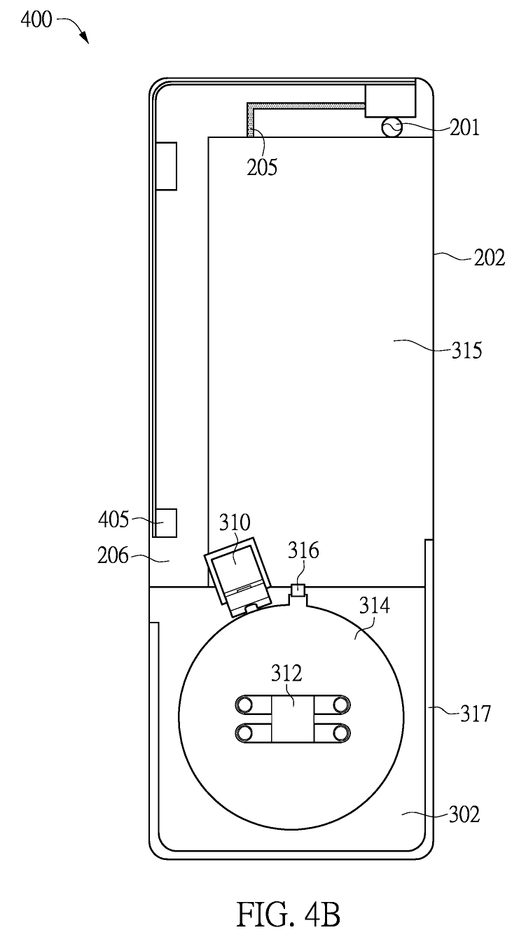

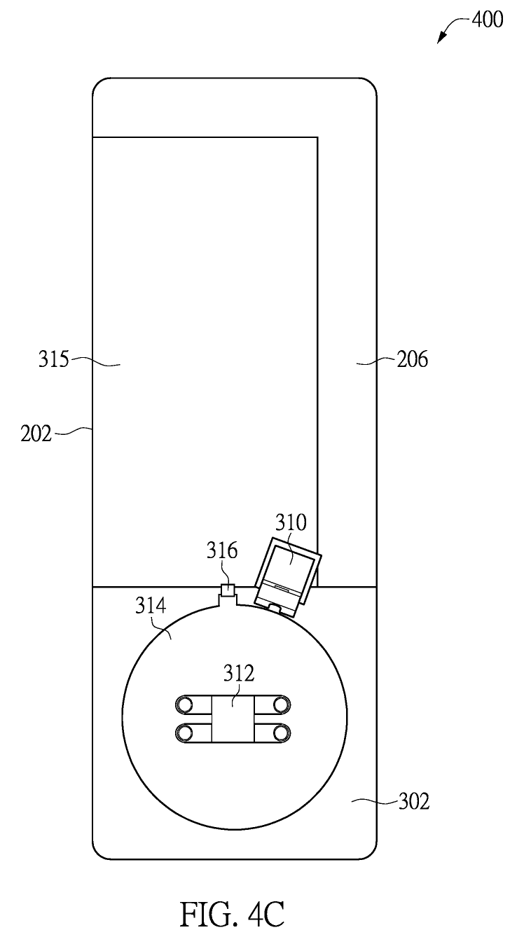

FIGS. 3A-3D show a schematic view of an electronic device 300 according to a second embodiment of the present disclosure. Similar to the embodiment shown in FIGS. 2A-2B, the electronic device 300 in FIGS. 3A-3D also includes a substrate 202 and an antenna 204, wherein the antenna 204 is disposed in the antenna clearance region 206. Compared to the first embodiment shown in FIGS. 2A-2B, the arrangement of components for the electronic device 300 in the second embodiment shown in FIGS. 3A-3D is adjusted, and a battery accommodation region 302 is defined on the substrate 202 for installation of the battery 114. A negative contact 312 and a battery ground portion 314 are disposed in the battery accommodation region 302, the negative contact 312 is configured to contact the negative terminal of the battery 114, and the negative contact 312 is connected to the battery ground portion 314. In some variant embodiments, the negative contact 312 can be omitted to allow the battery 114 to directly contact the battery ground portion 314. In other words, the battery ground portion 314 can be directly or indirectly connected to the negative terminal of the battery 114. The position of the battery accommodation region 302 is configured to allow the battery 114 and the battery ground portion 314 to avoid (e.g., to be arranged out of) the antenna clearance region 206 to prevent interference with the antenna 204; in other words, projection regions defined by projecting the battery ground portion 314 and the antenna clearance region 206 onto the substrate 202 are not overlapped with each other. By reducing the interference between the battery 114 and the antenna 204, the efficiency of the antenna 204 is improved. In some embodiments, the battery ground portion 314 and the system ground portion 315 can be separated from each other, and an inductor element 316 can be connected between the battery ground portion 314 and the system ground portion 315. The minimum spacing between the battery ground portion 314 and the system ground portion 315 can be greater than or equal to 1.5 mm; this can further reduce the interference induced between the battery ground portion 314 and the system ground portion 315. In practice, the battery accommodation region 302 can optionally be configured to include or exclude other components not shown in FIGS. 3A-3D; in some embodiments, the battery accommodation region 302 can be an area dedicated for the battery 114, used only for the battery 114 and its related components such as the positive contact 310, the negative contact 312, and the battery ground portion 314. This can reduce the interference of the battery 114 to the circuit system of the electronic device 300. Although FIG. 3B shows only one battery 114, two or more batteries 114 can be stacked as needed, or different batteries 114 can be installed on different surfaces of the substrate 202. In this embodiment, the battery 114 is installed on the first surface of the substrate 202 (FIGS. 3B and 3C), and the second surface of the substrate 202 (FIG. 3D) is provided without a battery disposed thereon. In some variant embodiments, a battery can also be disposed on the second surface of the substrate 202, which will be described later with reference to FIGS. 4A-4C.

Optionally, the electronic device 300 can further include an extended ground portion 317. The extended ground portion 317 can be a metal piece with height (as shown in FIGS. 3A and 3B) or a printed conductive line (i.e., a flat conductive line without significant height, not shown in the drawings). In some embodiments, projection regions defined by projecting the extended ground portion 317 and the antenna clearance region 206 onto the substrate 202 are not overlapped with each other. The extended ground portion 317 is connected to the system ground portion 315, so the extended ground portion 317 can extend the electrical length of the antenna 204, thereby improving the efficiency of the antenna 204. For example, the total electrical length formed by the radiating portion of the antenna 204 (e.g., the L-shaped portion of the antenna 204 shown in FIGS. 3A and 3B) and the ground portion (e.g., the extended ground portion 317 and the system ground portion 315) can satisfy the condition of ≥ λ/2, where λ is the wavelength corresponding to the operating frequency of the antenna 204. The radiating portion and the ground portion can each account for half of the total electrical length, which is about ≥ λ/4. In practice, the length of the antenna 204 and the extended ground portion 317 can be designed according to the operating frequency of the antenna 204; for example, in some embodiments, the total length of the antenna 204 is about 59 mm, and the total length of the extended ground portion 317 is about 71 mm. The extended ground portion 317 surrounds at least part of the battery ground portion 314. As shown in FIG. 3B, since the extended ground portion 317 has a height, the extended ground portion 317 can at least partially cover the side of the battery 114. When the height of the extended ground portion 317 is increased, the radiation area can be increased, thus enhancing the effects of the extended ground. Testing shows that when the height of the extended ground portion 317 is greater than or equal to 3 mm, the efficiency of the antenna 204 is significantly improved.

FIGS. 3C and 3D respectively show the first and second surfaces of the substrate 202 of the electronic device 300. In this embodiment, the positive contact 310, the negative contact 312, the battery ground portion 314, the inductor element 316, and the extended ground portion 317 are disposed on the first surface along with the antenna 204. In some variant embodiments, the positive contact 310, the negative contact 312, the battery ground portion 314, the inductor element 316, and the extended ground portion 317 can be disposed on one or both of the first and second surfaces of the substrate 202.

FIGS. 4A-4C show schematic views of an electronic device 400 according to a third embodiment of the present disclosure, which is a variation of the second embodiment. Some of the differences between the third embodiment (FIGS. 4A-4C) and the second embodiment (FIGS. 3A-3D) are described as follows. Firstly, the antenna 404 shown in FIG. 4A has a different form compared to the antenna 204 shown in FIG. 3A. The antenna 204 shown in FIG. 3A is an elevated structure, making it suspended relative to the substrate 202. The antenna 404 shown in FIG. 4A is changed into a wall structure 405 standing on the substrate 202. In some variant embodiments, the antennas 204 and 404 can be changed into various types of antennas, such as inverted-F antennas (IFA), planar inverted-F antennas (PIFA), monopole antennas, etc. The third embodiment also differs from the second embodiment in that the batteries 114 are installed on both the first and second surfaces of the substrate 202. Referring to FIGS. 4B and 4C, it can be seen that the positive contact 310, the negative contact 312, the battery ground portion 314, and the inductive element 316 are arranged on both the first and second surfaces of the substrate 202; thus, the batteries 114 can be respectively installed on both surfaces of the substrate 202, as shown in FIG. 4A.

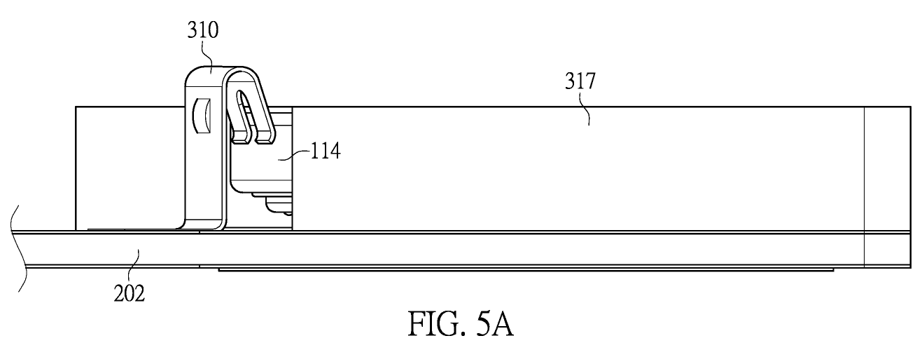

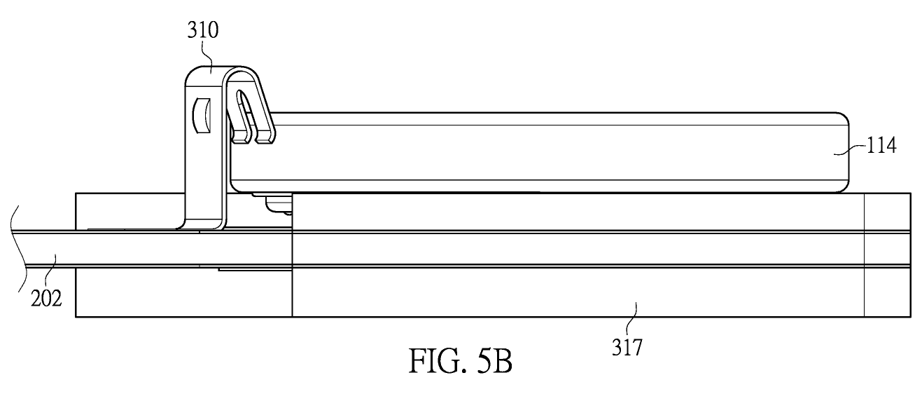

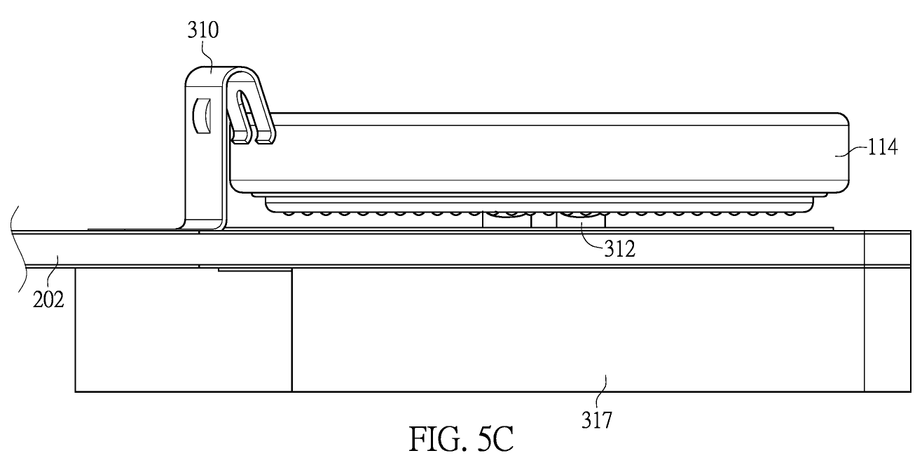

FIGS. 5A-5C show different extension configurations for the extended ground portion 317. FIG. 5A shows the extended ground portion 317 extending only along the first surface of the substrate 202; FIG. 5B shows the extended ground portion 317 extending along both the first and second surfaces of the substrate 202; FIG. 5C shows the extended ground portion 317 extending only along the second surface of the substrate 202. In some variant embodiments, the extended ground portion 317 may extend through the substrate 202 itself. When the battery 114 is installed, the height of the extended ground portion 317 can: (1) not cover the battery 114; (2) partially cover the battery 114; or (3) completely cover the battery 114. The extended ground portion 317 and the battery 114 can be arranged on a same surface or different surfaces of the substrate 202. The configurations of the extended ground portion 317 shown in FIGS. 5A-5C can be applied to the first to third embodiments shown in FIGS. 2A-4C, as well as various other variant embodiments not shown in the drawings.

FIG. 6 shows an antenna efficiency graph under different electronic device configurations. Configuration 1 corresponds to the conventional electronic device configuration of prior art shown in FIGS. 1A-1C, acting as the control group. Configuration 2 corresponds to the electronic device configuration shown in FIGS. 2A-2B. Configuration 3 corresponds to the electronic device configuration shown in FIGS. 3A-3D, but the extended ground portion 317 is changed into a printed conduction line rather than being a metal piece with height. Configuration 4 corresponds to the electronic device configuration shown in FIGS. 3A-3D, and the extended ground portion 317 is a metal piece with a height greater than or equal to 3 mm. Specifically, in the frequency band of approximately 900 MHz to 930 MHz, the antenna efficiency for Configuration 1 is about 23%-25%, the antenna efficiency for Configuration 2 is about 30%-33%, the antenna efficiency for Configuration 3 is about 48%-55%, and the antenna efficiency for Configuration 4 is about 55%-61%. From the comparison of antenna efficiencies for Configuration 1 to Configuration 4 shown in FIG. 6, it can be seen that each embodiment of the present disclosure shown in FIGS. 2A-3D has improved antenna efficiency compared to the conventional electronic device of prior art shown in FIGS. 1A-1C.

It should be noted that the various embodiments shown in FIGS. 2A-5C of the present disclosure may have various modifications. For example, the battery 114 is exemplified as a lithium battery, but it can be other types of batteries. The positive contacts 210, 310 and the negative contacts 212, 312 used for the battery 114 can have various shapes. The antennas 204, 404 can have various shapes and can be interchanged among various types of antennas, such as inverted F-type antennas, planar inverted F-type antennas, monopole antennas, etc. The battery ground portions 214, 314 can have other shapes besides being circular. The extended ground portion 317 can have other shapes besides being U-shaped. In addition, the features described for different embodiments of the present disclosure can be respectively arranged and combined. Other various modifications on the embodiments of the present disclosure are not exhaustively listed herein.

The foregoing description of the exemplary embodiments of the present disclosure has been presented only for the purposes of illustration and description and is not intended to be exhaustive or to limit the present disclosure. Many modifications and variations are possible in light of the above teaching.

The embodiments were chosen and described in order to explain the principles of the present disclosure and their practical applications. Alternative embodiments will become apparent to those skilled in the art to which the present disclosure pertains without departing from its spirit and scope.

What is claimed is:

1. An electronic device capable of operating with a battery installed, the electronic device comprising:
a substrate;
an antenna disposed on the substrate;
a system ground portion disposed on the substrate;
a battery ground portion configured to be connected to a negative terminal of the battery; and
an inductor element;
wherein the battery ground portion and the system ground portion are separate from each other, and the inductor element is connected between the battery ground portion and the system ground portion.

2. The electronic device according to claim 1, wherein the antenna comprises an antenna ground portion, and the antenna ground portion is connected to the system ground portion.

3. The electronic device according to claim 1, wherein the substrate comprises an antenna clearance region, the antenna is disposed in the antenna clearance region, and projection regions defined by projecting the battery ground portion and the antenna clearance region onto the substrate are not overlapped with each other.

4. The electronic device according to claim 3, wherein the substrate comprises a first surface and a second surface, and the battery ground portion is disposed on one or both of the first surface and the second surface.

5. The electronic device according to claim 1, further comprising an extended ground portion, the extended ground portion being connected to the system ground portion, and the extended ground portion surrounding at least a part of the battery ground portion.

6. The electronic device according to claim 5, wherein the extended ground portion is a printed conductive line.

7. The electronic device according to claim 5, wherein the extended ground portion is a metal piece that has a height.

8. The electronic device according to claim 7, wherein the height is 3 mm or above.

9. The electronic device according to claim 5, wherein the substrate comprises a first surface and a second surface, and the extended ground portion is disposed on one or both of the first surface and the second surface.

10. The electronic device according to claim 1, wherein a minimum spacing between the battery ground portion and the system ground portion is greater than or equal to 1.5 mm.

11. The electronic device according to claim 5, wherein the substrate comprises an antenna clearance region, the antenna is disposed in the antenna clearance region, and projection regions defined by projecting the extended ground portion and the antenna clearance region onto the substrate are not overlapped with each other.

12. An electronic device capable according to operating with a battery installed, the electronic device comprising:
a substrate including an antenna clearance region;
an antenna disposed in the antenna clearance region;
a system ground portion disposed on the substrate; and
a battery ground portion configured to be connected to a negative terminal of the battery;
wherein projection regions defined by projecting the battery ground portion and the antenna clearance region onto the substrate are not overlapped with each other.

13. The electronic device according to claim 12, wherein the antenna comprises an antenna ground portion, and the antenna ground portion is connected to the system ground portion.

14. The electronic device according to claim 12, wherein the substrate comprises a first surface and a second surface, and the battery ground portion is disposed on one or both of the first surface and the second surface.

15. The electronic device according to claim 12, further comprising an extended ground portion, the extended ground portion being connected to the system ground portion, and the extended ground portion surrounding at least a part of the battery ground portion.

16. The electronic device according to claim 15, wherein the extended ground portion is a printed conductive line.

17. The electronic device according to claim 15, wherein the extended ground portion is a metal piece that has a height, and the height is 3 mm or above.

18. The electronic device according to claim 15, wherein the substrate comprises a first surface and a second surface, and the extended ground portion is disposed on one or both of the first surface and the second surface.

19. The electronic device according to claim 12, wherein a minimum spacing between the battery ground portion and the system ground portion is greater than or equal to 1.5 mm.

20. The electronic device according to claim 15, wherein projection regions defined by projecting the extended ground portion and the antenna clearance region onto the substrate are not overlapped with each other.
